(19) United States
(12) Patent Application Publication
(10) Pub. No.: US 2017/0179236 A1
(43) Pub. Date: Jun. 22, 2017

(54) METHOD OF PRODUCING SILICON CARBIDE EPITAXIAL SUBSTRATE, SILICON CARBIDE EPITAXIAL SUBSTRATE, AND SILICON CARBIDE SEMICONDUCTOR DEVICE

(71) Applicant: Sumitomo Electric Industries, Ltd., Osaka-shi (JP)

(72) Inventor: Toru Hiyoshi, Osaka-shi (JP)

(21) Appl. No.: 15/443,785

(22) Filed: Feb. 27, 2017

Related U.S. Application Data
(62) Division of application No. 14/824,938, filed on Aug. 12, 2015.

(30) Foreign Application Priority Data
Sep. 22, 2014 (JP) 2014-192522

(51) Int. Cl. H01L 29/16; H01L 21/02; H01L 29/861; H01L 21/324; H01L 21/04; H01L 29/36; H01L 21/306

(52) U.S. Cl. CPC H01L 29/1608; H01L 29/36; H01L 21/02378; H01L 21/02529; H01L 21/02634; H01L 21/30625; H01L 21/324; H01L 21/0475; H01L 21/0262; H01L 29/861

(57) ABSTRACT

A method of producing a silicon carbide epitaxial substrate includes steps of: preparing a silicon carbide substrate; and forming a silicon carbide layer on the silicon carbide substrate. In this production method, in the step of forming the silicon carbide layer, a step of growing an epitaxial layer and a step of polishing a surface of the epitaxial layer are repeated twice or more.

### CROSS-REFERENCE TO RELATED APPLICATIONS

This application is a Divisional of U.S. patent application Ser. No. 14/824,938, filed Aug. 12, 2015, which claims the benefit of Japanese Patent Application No. 2014-192522, filed Sep. 22, 2014.

### BACKGROUND OF THE INVENTION

Field of the Invention

The present invention relates to a method of producing a silicon carbide epitaxial substrate, a silicon carbide epitaxial substrate, and a silicon carbide semiconductor device.

Description of the Background Art

Silicon carbide (SiC), which has high dielectric breakdown electric field strength, is drawing attention as a material to replace silicon (Si) for a next-generation power semiconductor device (also referred to as “power device”). Particularly, since SiC is an indirect gap semiconductor and intrinsically has a long carrier lifetime, SiC is greatly expected for a high breakdown voltage bipolar semiconductor device in which an effect of conductivity modulation determines the performance of the semiconductor device (for example, see Japanese Patent Laying-Open No. 2008-53667 and Hiyoshi et al., (T. Hiyoshi et al., “Reduction of Deep Levels and Improvement of Carrier Lifetime in n-Type 4H-SiC by Thermal Oxidation” Appl. Phys. Express 2 041101 (2009)).

### SUMMARY OF THE INVENTION

A bipolar semiconductor device employing SiC is expected to exhibit a breakdown voltage of not less than 10 kV, which cannot be attained by Si. In order to implement a bipolar semiconductor device having such a very high breakdown voltage of not less than 10 kV, a thick and high-quality epitaxial layer (of not less than 100 μm, for example) is needed. However, for growing a thick SiC epitaxial layer, no producing means for practical use has not been established yet due to the following problems (i) to (iii).

(i) A thicker epitaxial layer means a longer growth time. An epitaxial layer is grown on a substrate placed in, for example, a CVD (Chemical Vapor Deposition) furnace. However, when growth time becomes long, the crystal source material is also deposited on the inner wall of the CVD furnace, and the deposit falls on the epitaxial layer that is growing, with the result that the foreign matter is embedded in the epitaxial layer or a portion thereof falls off together with the grown crystal to cause a hole-like surface defect (also referred to as “downfall”). The downfall is a critical defect for semiconductor devices, and greatly affects yield of SiC epitaxial substrates.

(ii) For SiC, there are various type of polytypes but 4H type SiC crystal (4H-SiC) is considered to be the most useful for semiconductor devices. In general, for growth of a SiC epitaxial layer, step-flow growth, which is lateral growth from an atomic level step on a substrate with a slight off angle, is performed to suppress inclusion of a different type of polytype (polytype other than the intended polytype). However, when growing a thick epitaxial layer by the step-flow growth, a fast-growing step reaches a slow-growing step and is combined therewith to form a large bunch, i.e., step-bunching takes place inevitably. The step-bunching is a factor that decreases reliability of an oxide film in a semiconductor device.

FIG. 27 is a schematic view showing that a gate oxide film 126 and a gate electrode 132 are formed on an epitaxial layer 111 having step-bunching therein in a MOSFET (Metal-Oxide Semiconductor Field-Effect Transistor), for example. A direction D in FIG. 27 represents a direction of step-flow growth. In FIG. 27, a large step ST is caused by step-bunching. In such a step ST, electric field concentration is likely to take place to decrease reliability of gate oxide film 126. Moreover, because resulting crystal planes differ between a terrace TE and a side wall SW of step ST, the film thickness of gate oxide film 126 formed thereon also becomes different, thereby promoting dielectric breakdown. Generally, gate oxide film 126 has a thickness of, for example, about 50 to 60 nm, and when the step (step height H in FIG. 27) caused by the step-bunching is more than 10 nm, it becomes difficult to produce a semiconductor device for practical use.

(iii) Further, in a thick epitaxial layer, a problem is also provided by existence of point defects called “Z_{1/2} center” and associated with carbon vacancy. Z_{1/2} center is so-called “lifetime killer”; when the density thereof becomes high, carrier lifetime becomes short to lead to failure of occurrence of sufficient conductivity modulation, with the result that a bipolar semiconductor device having a low on resistance is not obtained. It is considered that due to influence of Z_{1/2} center, the carrier lifetime is short even though SiC is an indirect gap semiconductor.

In Japanese Patent Laying-Open No. 2008-53667, interstitial carbon atoms are introduced into a surface layer of an epitaxial layer by means of ion implantation and then the interstitial carbon atoms are diffused by heating to be combined with Z_{1/2} center, thereby reducing Z_{1/2} center. However, there are limits in term of ion implantation depth and implantation amount into SiC, and it is difficult to diffuse interstitial carbon atoms to a deep layer of a thick epitaxial layer of more than 100 μm.

On the other hand, Hiyoshi et. al, indicate that when a surface of an epitaxial layer (SiC) is thermally oxidized to form a SiO₂ film, carbon atoms (C) are released and part of the carbon atoms (C) are diffused in SiC, and indicate that Z_{1/2} center can be accordingly reduced. However, for example, when this technique is applied to an epitaxial layer of not less than 100 μm, heat treatment needs to be performed for 48 hours or more, thus resulting in decreased productivity.

In view of the above-described problems, it is an object to provide a silicon carbide epitaxial substrate having a high-quality and thick epitaxial layer.

A method of producing a silicon carbide epitaxial substrate according to one embodiment of the present invention includes steps of: preparing a silicon carbide substrate; and forming a silicon carbide layer on the silicon carbide substrate. In this production method, in the step of forming the silicon carbide layer, a step of growing an epitaxial layer and a step of polishing a surface of the epitaxial layer are repeated twice or more.

A method of producing a silicon carbide epitaxial substrate according to another embodiment of the present invention includes steps of: preparing a silicon carbide substrate; and forming a silicon carbide layer on the silicon carbide substrate. In this production method, in the step of forming the silicon carbide layer, a step of growing an epitaxial layer and a step of introducing carbon into the epitaxial layer are repeated twice or more and an annealing step of diffusing the carbon is performed once or more.

A silicon carbide epitaxial substrate according to one embodiment of the present invention includes a silicon carbide substrate, and a silicon carbide layer epitaxially grown on the silicon carbide substrate. The silicon carbide layer includes Z_{1/2} center. A maximum value of a density of Z_{1/2} center is at a position separated from an interface between the silicon carbide substrate and the silicon carbide layer in a depth direction of the silicon carbide layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a first production method included in a method of producing a silicon carbide epitaxial substrate according to one embodiment of the present invention.

FIG. 2 is a flowchart schematically showing a second production method included in the method of producing the silicon carbide epitaxial substrate according to the embodiment of the present invention.

FIG. 3 is a flowchart schematically showing a third production method included in the method of producing the silicon carbide epitaxial substrate according to the embodiment of the present invention.

FIG. 4 is a schematic cross sectional view illustrating a preparing step.

FIG. 5 is a schematic cross sectional view illustrating a part of the first production method.

FIG. 6 is a schematic cross sectional view illustrating a part of the first production method.

FIG. 7 is a schematic cross sectional view illustrating a part of the first production method.

FIG. 8 is a schematic cross sectional view illustrating a part of the first production method.

FIG. 9 is a schematic cross sectional view showing an example of a configuration of a silicon carbide epitaxial substrate according to the first production method.

FIG. 10 is a schematic cross sectional view illustrating a part of the second production method.

FIG. 11 is a schematic cross sectional view illustrating a part of the second production method.

FIG. 12 is a schematic cross sectional view illustrating a part of the second production method.

FIG. 13 is a schematic cross sectional view illustrating a part of the second production method.

FIG. 14 is a schematic cross sectional view illustrating a part of the second production method.

FIG. 15 is a schematic cross sectional view illustrating a part of the second production method.

FIG. 16 is a schematic cross sectional view showing an example of a configuration of a silicon carbide epitaxial substrate according to the second production method.

FIG. 17 is a schematic cross sectional view illustrating a part of the third production method.

FIG. 18 is a schematic cross sectional view illustrating a part of the third production method.

FIG. 19 is a schematic cross sectional view illustrating a part of the third production method.

FIG. 20 is a schematic cross sectional view illustrating a part of the third production method.

FIG. 21 is a schematic cross sectional view showing an example of a configuration of a silicon carbide epitaxial substrate according to the third production method.

FIG. 22 is a schematic view showing an example of a configuration of a silicon carbide epitaxial substrate according to one embodiment of the present invention.

FIG. 23 is a graph showing an example of a change in density of Z_{1/2} center in a depth direction in a silicon carbide layer of the silicon carbide epitaxial substrate according to the embodiment of the present invention.

FIG. 24 is a graph showing an example of a change in concentration of an impurity in the depth direction in the silicon carbide layer of the silicon carbide epitaxial substrate according to the embodiment of the present invention.

FIG. 25 is a schematic cross sectional view showing one example of a configuration of a silicon carbide semiconductor device according to one embodiment of the present invention.

FIG. 26 is a schematic view illustrating conductivity modulation in the silicon carbide semiconductor device according to the embodiment of the present invention.

FIG. 27 is a schematic view illustrating step-flow bunching.

### DESCRIPTION OF THE PREFERRED EMBODIMENTS

### Description of Embodiments of the Present Invention

First, embodiments of the present invention are listed and described.

[1] A method of producing a silicon carbide epitaxial substrate according to one embodiment of the present invention includes steps of: preparing (S100) a silicon carbide substrate; and forming (S201, S203) a silicon carbide layer on the silicon carbide substrate. In the step (S201, S203) of forming the silicon carbide layer, a step (S1) of growing an epitaxial layer and a step (S4) of polishing a surface of the epitaxial layer are repeated twice or more.

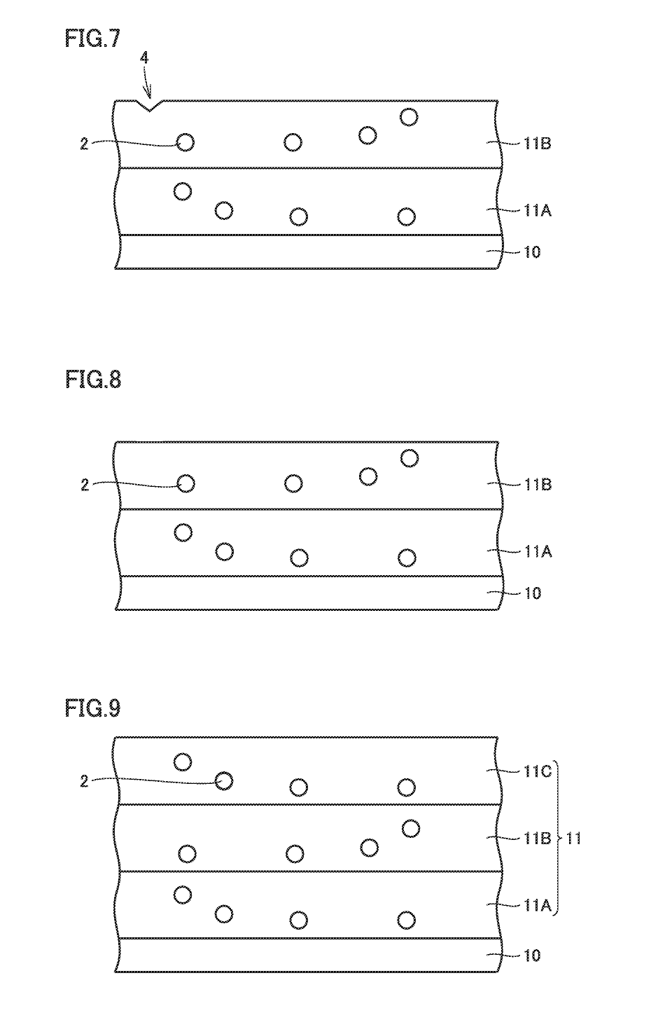

In this production method, the SiC epitaxial layer is grown intermittently in some steps, rather than growing it continuously. Namely, a thick SiC layer 11 is grown by repeating a series of steps (S21) as follows: a first epitaxial layer 11A having a predetermined thickness is grown (see FIG. 5); then the growth is temporarily interrupted; a surface of first epitaxial layer 11A is polished; foreign matters adhered to the surface and surface defects 4 such as downfall are removed (see FIG. 6); and a second epitaxial layer 11B is grown thereon (see FIG. 7). According to this method, even an epitaxial layer having a thickness of not less than 100 μm can be grown while maintaining quality for practical use.

[2] In [1] described above, preferably, in the step of polishing, the surface of the epitaxial layer is polished by chemical mechanical polishing or mechanical polishing. This is because the chemical mechanical polishing (CMP) or the mechanical polishing (MP) allows for removal of large surface defects such as downfall.

[3] In [1] described above, preferably, in the step of polishing, the epitaxial layer is polished by not less than 1 μm. By polishing the surface of each epitaxial layer by not less than 1 μm, step-bunching can be reduced in the surface of each epitaxial layer, thereby suppressing the step-bunching from growing to be large. As a result, in the outermost surface of SiC layer 11, a step caused by the step-bunching can be suppressed to less than 10 nm.

[4] In [1] described above, preferably, in the step (S203) of forming the silicon carbide layer, each of a step (S2) of introducing carbon into the epitaxial layer and an annealing step (S3) of diffusing the carbon is performed once or more.

In the production method of [1] described above, by introducing carbon 6 into at least one of the epitaxial layers included in the SiC layer and diffusing the carbon by annealing, Z_{1/2} center 2 included in the SiC layer can be reduced. Here, the step (S2) of introducing the carbon may be performed to each epitaxial layer or may be performed only to the uppermost layer (third epitaxial layer 13C in FIG. 21). Moreover, the annealing step (S3) may be performed whenever carbon is introduced or may be collectively performed once at the end.

[5] A method of producing a silicon carbide epitaxial substrate according to another embodiment of the present invention includes steps of: preparing (S100) a silicon carbide substrate; and forming (S202) a silicon carbide layer on the silicon carbide substrate. In the step (S202) of forming the silicon carbide layer, a step (S1) of growing an epitaxial layer and a step (S2) of introducing carbon into the epitaxial layer are repeated twice or more, and an annealing step (S3) of diffusing the carbon is performed once or more.

Also in this production method, the SiC epitaxial layer is grown intermittently in some steps, rather than growing it continuously. Further, carbon 6 is introduced into and diffused by annealing in at least two of the epitaxial layers, preferably, all the epitaxial layers. According to this method, Z_{1/2} center 2 can be reduced in a range from the surface layer to the deep layer of the SiC layer. Therefore, the SiC epitaxial substrate obtained by this method satisfies characteristics required for ultra-high breakdown voltage bipolar semiconductor devices.

[6] In [4] or [5] described above, preferably, the step (S2) of introducing the carbon is at least performed to the epitaxial layer, which is to be an uppermost layer. This is because the introduction of carbon into at least the uppermost layer leads to reduction of Z_{1/2} center 2. Further, more preferably, the step (S2) of introducing the carbon is performed to all the epitaxial layers. This is because Z_{1/2} center 2 can be reduced further.

[7] In [4] to [6] described above, preferably, in the step (S2) of introducing the carbon, carbon 6 is introduced by ion implantation or is introduced by thermally oxidizing a portion of the epitaxial layer. According to the ion implantation, the carbon can be readily introduced into the epitaxial layer. Alternatively, by thermally oxidizing a portion (for example, surface) of the epitaxial layer to generate SiO₂, carbon is released from SiC as mentioned above, with the result that the carbon can be introduced into the epitaxial layer.

[8] In [4] to [7] described above, preferably, an annealing temperature in the annealing step (S3) is not less than 1700° C. and not more than 1800° C. This is because carbon 6 can be diffused more securely.

[9] In [1] to [8] described above, preferably, the epitaxial layer has a thickness of not less than 50 μm and not more than 100 μm. By interrupting the epitaxial growth in accordance with such an interval and performing polishing or introduction of carbon, productivity for a thick epitaxial layer can be improved.

[10] In [1] to [8] described above, preferably, the silicon carbide layer has a thickness of not less than 100 μm. This is because a SiC layer of not less than 100 μm with reduced surface defects and point defects satisfies characteristics required for ultra-high breakdown voltage bipolar semiconductor devices.

[11] A silicon carbide epitaxial substrate according to one embodiment of the present invention includes a silicon carbide substrate 10, and a silicon carbide layer epitaxially grown on silicon carbide substrate 10. The silicon carbide layer includes Z_{1/2} center 2. A maximum value Pz of a density of Z_{1/2} center 2 is at a position separated from an interface between silicon carbide substrate 10 and the silicon carbide layer in a depth direction of the silicon carbide layer.

This SiC epitaxial substrate is obtained by, for example, the production method of [4] or [5] described above. Therefore, the SiC layer includes a configuration resulting from the stepwise epitaxial growth and the introduction of carbon.

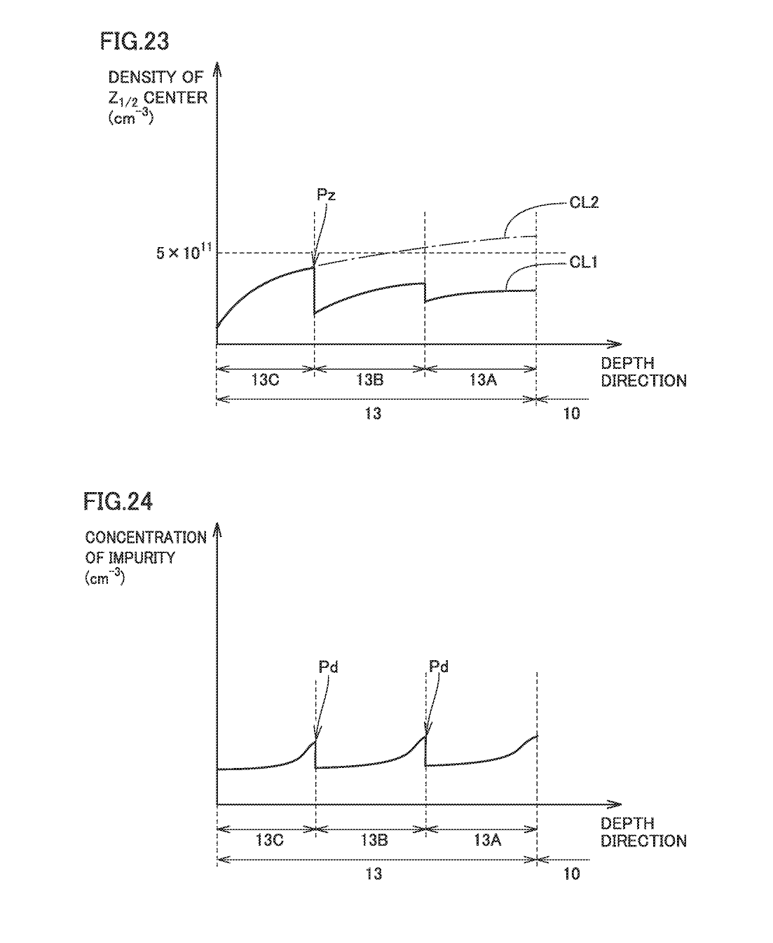

FIG. 23 is a graph showing a change in density of Z_{1/2} center 2 in the depth direction of the SiC layer (third SiC layer 13). In FIG. 23, the horizontal axis represents the depth direction of the SiC layer (direction from the surface of third SiC layer 13 toward SiC substrate 10 in FIG. 21), whereas the vertical axis represents the density of Z_{1/2} center 2. A curve CL1 in FIG. 23 indicates a change in density of Z_{1/2} center 2 in [11] described above, whereas a curve CL2 indicates a change in density of Z_{1/2} center 2 in the SiC layer obtained by, for example, the method of Japanese Patent Laying-Open No. 2008-53667.

In curve CL2, Z_{1/2} center is reduced in the vicinity of the surface layer of the SiC layer, but the density thereof is more increased at a deeper position and the density is the maximum at the interface between the SiC substrate and the SiC layer. With such an epitaxial layer, sufficient conductivity modulation cannot be expected. In contrast, in curve CL1, maximum value Pz of the density of Z_{1/2} center 2 is at a position separated from the interface between SiC substrate 10 and the SiC layer (third SiC layer 13). This is because carbon 6 has been introduced and diffused by annealing also in a layer (at least one of first epitaxial layer 13A and second epitaxial layer 13B) other than the uppermost layer (third epitaxial layer 13C). In this SiC layer, the density of Z_{1/2} center 2 is low also in the range from the intermediate layer to the vicinity of the deep layer, so that an effect of conductivity modulation can be expected which satisfies ultra-high breakdown voltage bipolar semiconductor devices.

[12] In [11] described above, preferably, maximum value Pz is not more than 5×10¹¹ cm⁻³. This is because the effect of conductivity modulation can be increased further.

[13] In [11] or [12] described above, preferably, the silicon carbide layer further includes a p type or n type impurity, and a peak Pd of a concentration of the impurity is at a position separated from the interface between silicon carbide substrate 10 and the silicon carbide layer in the depth direction of the silicon carbide layer.

In epitaxial growth involving introduction of an impurity (dopant), the concentration of the impurity needs to be made slightly high during a period of time from the early stage of the growth till the growth becomes stable. Therefore, when epitaxial growth is performed in the stepwise manner, a peak of the impurity is caused to correspond to the interruption of the growth in the depth direction of the epitaxial layer. Therefore, when the epitaxial growth is performed in the stepwise manner, at least one peak of the impurity exists at a position separated from the interface between SiC substrate 10 and the SiC layer (third SiC layer 13) (see FIG. 24). Here, examples of the p type impurity include aluminum (Al) and the like, whereas examples of the n type impurity include nitrogen (N) and the like.

[14] In [13] described above, preferably, a plurality of peaks of the concentration of the impurity exist in the depth direction.

The number of peaks of the concentration of the impurity corresponds to the plurality of steps in which the epitaxial growth has been performed. Therefore, the existence of the plurality of peaks indicates that a series of steps have been repeated as follows: an epitaxial layer having a predetermined thickness is grown during epitaxial growth; then the growth is temporarily interrupted; and the epitaxial layer is grown thereon. With such stepwise epitaxial growth, surface defects such as downfall can be removed or a polishing process for reducing step-bunching can be performed whenever epitaxial growth is performed.

[15] In [13] or [14] described above, preferably, a peak interval of the concentration of the impurity is not less than 50 μm and not more than 100 μm in the depth direction.

The fact that the peak interval of the concentration of the impurity is not less than 50 μm and not more than 100 μm indicates that, for example, third SiC layer 13 includes a plurality of epitaxial layers of not less than 50 μm and not more than 100 μm. Such a SiC layer is high in productivity and has reduced Z_{1/2} center in the range from the surface layer to the deep layer as described above.

[16] In [11] to [14] described above, preferably, the silicon carbide layer has a thickness of not less than 100 μm. This is because a thick drift layer applicable to ultra-high breakdown voltage bipolar semiconductor devices can be realized.

[17] A silicon carbide semiconductor device according to one embodiment of the present invention is a silicon carbide semiconductor device obtained using the silicon carbide epitaxial substrate of [11] to [16] described above. This silicon carbide semiconductor device exhibits excellent performance because the point defects of the epitaxial layer (third SiC layer 13) have been reduced. Particularly, in the case of a bipolar semiconductor device, high breakdown voltage is exhibited depending on the thickness of the drift layer (third SiC layer 13), while a low on resistance can be exhibited due to sufficient conductivity modulation.

### Details of Embodiments of the Present Invention

The following describes one embodiment of the present invention (hereinafter, also referred to as “the present embodiment”) in detail, but the present embodiment is not limited thereto. In the description below, the same or corresponding elements are given the same reference characters and are not described repeatedly. Regarding crystallographic indications in the present specification, an individual orientation is represented by [], a group orientation is represented by <>, an individual plane is represented by ( ), and a group plane is represented by {}. In addition, a crystallographically negative index is supposed to be indicated by putting “-” (bar) above a numeral, but is indicated by putting the negative sign before the numeral in the present specification.

### First Embodiment

### Method for Producing Silicon Carbide Epitaxial Substrate

A first embodiment presents a method of producing a SiC epitaxial substrate including a SiC single crystal substrate and a SiC layer epitaxially grown thereon. This production method includes a first production method, a second production method, and a third production method as follows.

[1. First Production Method]

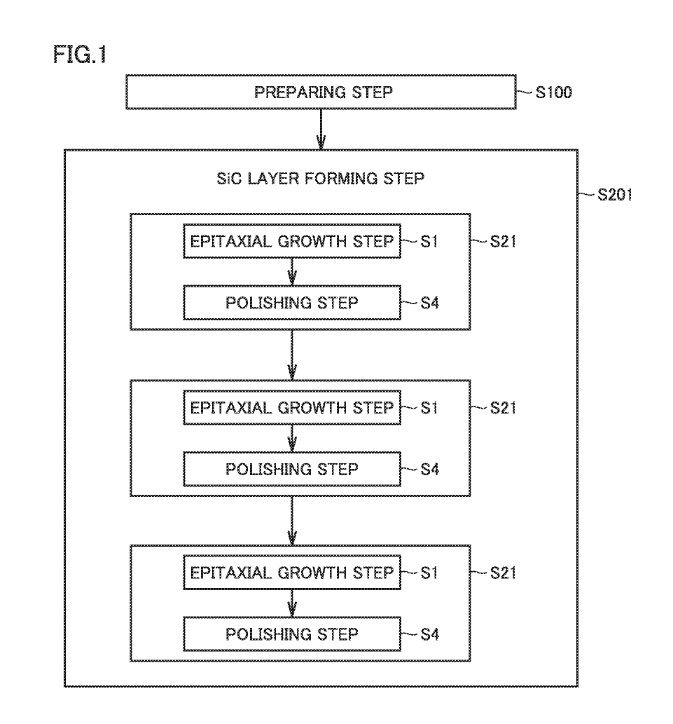

FIG. 1 is a flowchart schematically showing the first production method. With reference to FIG. 1, the first production method includes a preparing step (S100) and a first SiC layer forming step (S201). In the first production method, a series of steps (S21) including an epitaxial growth step (S1) and a polishing step (S4) are repeated twice or more in the first SiC layer forming step (S201). Here, FIG. 1 illustrates that the series of steps (S21) are repeated for 3 times, but the number of repetitions is not particularly limited as long as it is twice or more. However, in consideration of productivity (throughput), the number of repetitions is preferably about not more than 10 times, and is more preferably about not more than 5 times. Regarding the number of repetitions, the same applies to the second and third production methods described below.

In the first production method, an epitaxial layer having a predetermined thickness is grown, and is then polished at its surface to remove a foreign matter adhered to the surface or surface defects such as downfall and to reduce a step caused by step-bunching. This is repeated to produce a high-quality thick epitaxial layer (first SiC layer 11) (free of surface defects and step-bunching). First SiC layer 11 thus obtained has few included foreign matters and surface defects, has small surface roughness resulting from step-bunching, and is therefore useful for any types of semiconductor devices including bipolar and unipolar semiconductor devices. Hereinafter, each step will be described.

[Preparing Step (S100)]

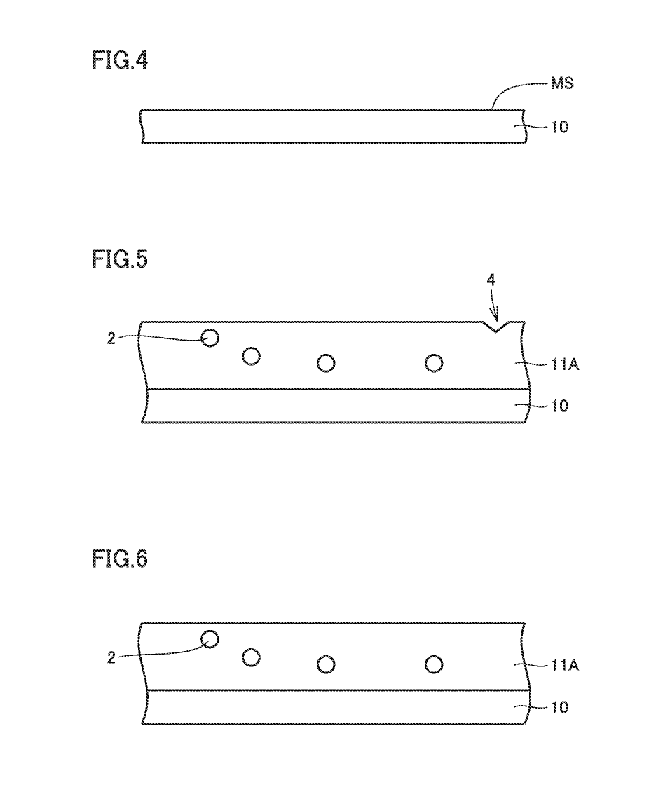

With reference to FIG. 4, a SiC substrate 10 (wafer) having a main surface MS is prepared in the preparing step (S100). SiC substrate 10 can be prepared by slicing a single crystal ingot, for example. A wire saw is used for the slicing, for example. The SiC desirably has a polytype of 4H-SiC because dielectric breakdown electric field strength is high. The plane orientation of SiC substrate 10 (plane orientation of main surface MS) corresponds to a {0001} plane, for example. Furthermore, SiC substrate 10 desirably has an off angle of several degrees relative to the {0001} plane, i.e., main surface MS is desirably inclined by several degrees relative to the {0001} plane. This is for controlling polytype by means of step-flow growth. SiC substrate 10 preferably has an off angle of not less than 1° and not more than 8°, more preferably, not less than 2° and not more than 7°, and particularly preferably, not less than 3° and not more than 5°. The off direction thereof is a <11-20> direction, for example.

[First SiC Layer Forming Step (S201)]

With reference to FIG. 1, in the first SiC layer forming step (S201), the series of steps (S21) including the epitaxial growth step (S1) and the polishing step (S4) are repeated twice or more. Hereinafter, each of the steps will be described with reference to figures.

[Epitaxial Growth Step (S1)]

First, with reference to FIG. 5, a first epitaxial layer 11A is grown on SiC substrate 10. First epitaxial layer 11A is grown by a CVD method, for example. For example, silane (SiH₄) and propane (C₃H₈) are used as source material gas and hydrogen (H₂) is used as carrier gas, and step-flow growth is performed under a temperature of about 1400° C. to 1700° C. Moreover, in doing so, an impurity (dopant) such as nitrogen (N) or phosphorus (P) may be introduced.

Although it depends on a target thickness of first SiC layer 11, first epitaxial layer 11A preferably has a thickness of, for example, not less than 50 μm and not more than 100 μm. This is because productivity is low when the thickness is less than 50 μm while inclusion of foreign matters may not be able to be sufficiently suppressed when the thickness is more than 100 μm. The thickness of first epitaxial layer 11A is more preferably not less than 60 μm and not more than 90 μm, and is particularly preferably not less than 70 μm and not more than 80 μm.

[Polishing Step (S4)]

With reference to FIG. 5, first epitaxial layer 11A having been grown includes a surface defect 4 such as downfall, Z_{1/2} center 2 (point defects), and the like. Moreover, large step-bunching may have caused roughness in surface. To address this, the surface of first epitaxial layer 11A is polished, thereby removing surface defect 4 as shown in FIG. 6 to reduce the step caused by the step-bunching. Removal of the point defects will be described later in detail with regard to the second production method.

For polishing means, CMP or MP can be used, for example. Colloidal silica slurry can be used for CMP, for example. An amount of polishing is preferably not less than 1 μm. This is because the step caused by the step-bunching can be accordingly suppressed to less than 10 nm in the outermost surface of first SiC layer 11. The amount of polishing is more preferably not less than 2 μm, and is particularly preferably not less than 3 μm. The upper limit of the amount of polishing is not particularly limited, but in consideration of throughput, the amount of polishing is not more than 10 μm, for example.

Next, with reference to FIG. 7, a second epitaxial layer 11B is grown on the polished surface of first epitaxial layer 11A (S1). Because surface defect 4 have been removed and the step caused by the step-bunching have been reduced in the polished surface of first epitaxial layer 11A, second epitaxial layer 11B can also be stably grown by step-flow growth. Then, as shown in FIG. 8, the surface of second epitaxial layer 11B is also polished. Accordingly, a surface defect 4 of second epitaxial layer 11B is removed, thereby reducing the step caused by the step-bunching.

In the first production method, the series of steps (S21) including the epitaxial growth step (S1) and the polishing step (S4) are repeated once again. That is, in the first production method, the series of steps (S21) are repeated 3 times in total. Accordingly, first SiC layer 11 is formed which includes first epitaxial layer 11A, second epitaxial layer 11B, and a third epitaxial layer 11C as shown in FIG. 9.

The thickness of first SiC layer 11 (the total thickness of the respective epitaxial layers) is preferably not less than 100 μm because this contributes to the blocking voltage performance of the semiconductor device. Moreover, in consideration of throughput, the thickness of first SiC layer 11 is not more than 400 μm, for example. When an ultra-high breakdown voltage bipolar semiconductor device is intended as a target, the thickness of first SiC layer 11 is preferably not less than 200 μm and not more than 300 μm. It should be noted that the layers (first epitaxial layer 11A and the like) of first SiC layer 11 may have the same thickness or different thicknesses.

[2. Second Production Method]

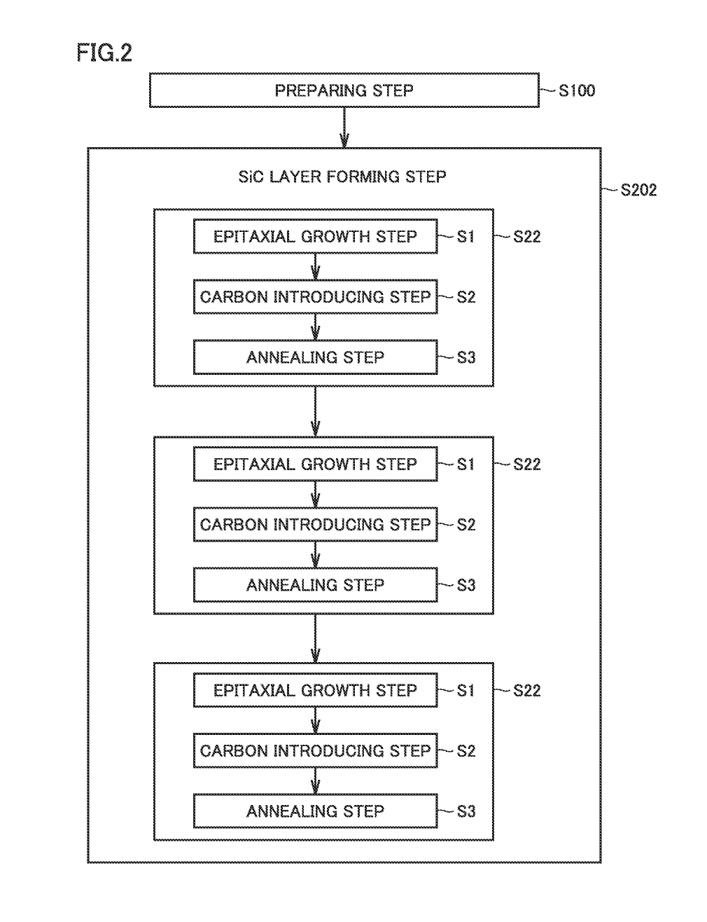

FIG. 2 is a flowchart schematically showing the second production method. With reference to FIG. 2, the second production method includes the preparing step (S100) and a second SiC layer forming step (S202). In the second production method, a series of steps (S22) including the epitaxial growth step (S1) and a carbon introducing step (S2) are repeated twice or more in the second SiC layer forming step (S202). Moreover, an annealing step (S3) of diffusing carbon is performed at least once.

In the second production method, the epitaxial layer is grown in two steps or more in the same manner as in the first production method, carbon 6 is introduced into at least one of the epitaxial layers formed below the uppermost layer, and annealing is performed to diffuse the introduced carbon 6 in second SiC layer 12. Carbon 6 thus diffused is combined with and eliminates Z_{1/2} center 2 (point defects).

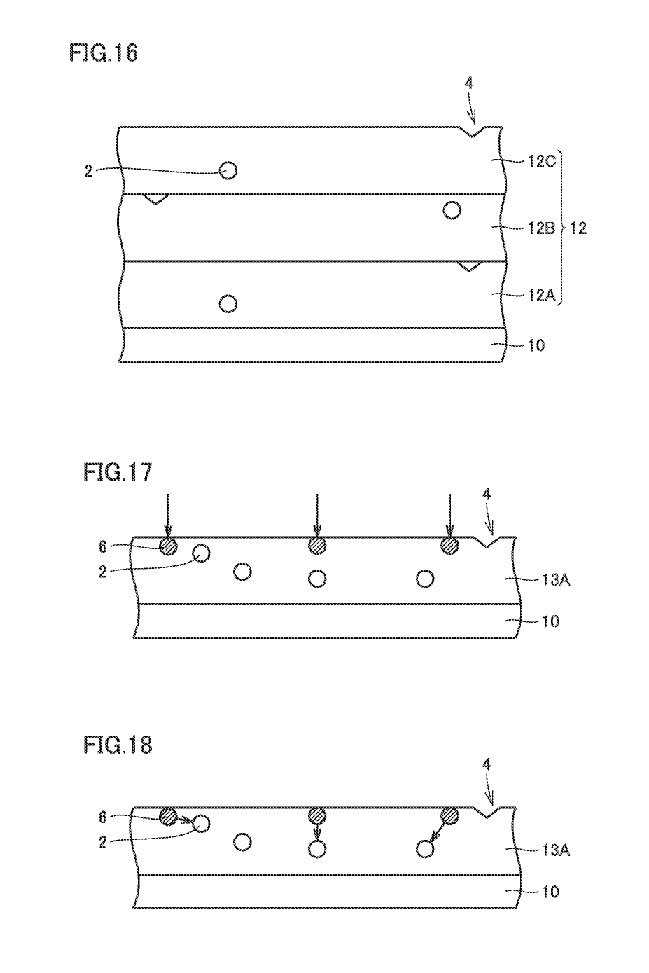

According to the second production method, even when second SiC layer 12 is a thick epitaxial layer of more than 100 μm, Z_{1/2} center 2, which is lifetime killer, can be reduced in not only the surface layer but also a range from the intermediate layer to the deep layer (see FIG. 16). Therefore, second SiC layer 12 obtained by the second production method is suitable for a bipolar semiconductor device, in which the carrier lifetime is important. Although the following describes each of the steps, the preparing step (S100) and the epitaxial growth step (S1) in the second production method are the same as those in the first production method described above and they are therefore not described repeatedly.

[Second SiC Layer Forming Step (S202)]

With reference to FIG. 2, in the second SiC layer forming step (S202), the series of steps (S22) including the epitaxial growth step (S1), the carbon introducing step (S2), and the annealing step (S3) are repeated twice or more.

Here, the annealing step (S3) may be performed whenever carbon is introduced or may be collectively performed once after the uppermost layer is formed. This is due to the following reason: by the heating during growth of an epitaxial layer (S1), carbon 6 having been introduced into the previous epitaxial layer can be diffused to some extent. However, it is more preferable to perform the annealing step (S3) whenever carbon 6 is introduced. This is to diffuse carbon 6 more securely.

Moreover, in the present embodiment, the step (S2) of introducing carbon is repeated twice or more, but it is desirable to perform the step of introducing carbon to at least the uppermost layer. This is because a SiC layer having reduced point defects in a wide range in the depth direction can be formed by reducing the point defects in the uppermost layer and at least one layer formed below the uppermost layer.

[Step (S2) of Introducing Carbon]

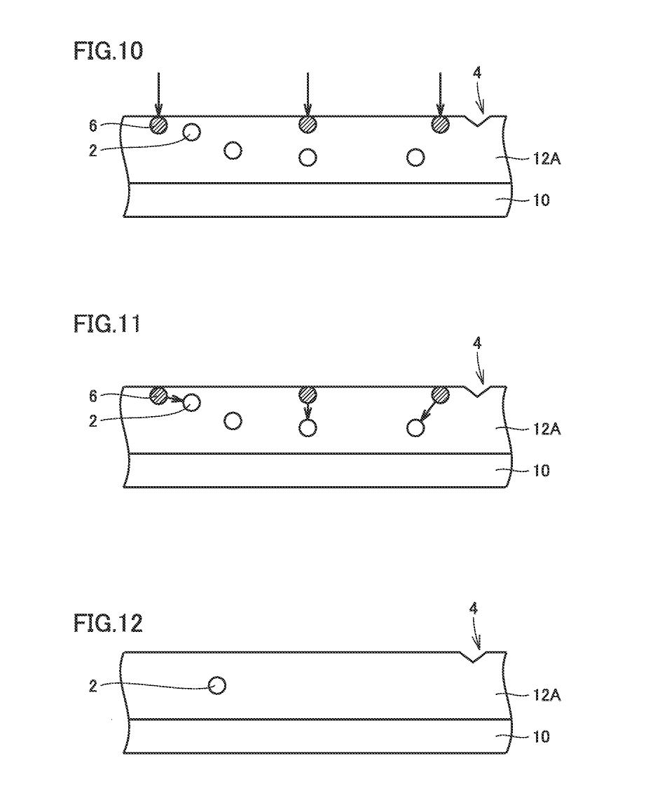

With reference to FIG. 10, carbon 6 is introduced into first epitaxial layer 12A having been grown. For means for introducing carbon, thermal oxidation or ion implantation can be used, for example. The thermal oxidation can be performed, for example, under oxygen atmosphere at 1100° C. to 1300° C. (preferably not less than 1200° C. and not more than 1300° C.) for about 5 minutes to 24 hours (preferably 1 hour to 10 hours). An oxide film (SiO₂) produced by the oxidation of SiC may be removed by etching.

The ion implantation can be performed, for example, at an implantation energy of about 10 keV to 1 MeV (preferably not less than 10 keV and not more than 300 keV) at a dose amount of about 1×10¹² to 1×10¹⁵cm² (preferably 5×10¹² to 5×10¹⁴cm²).

[Annealing Step (S3)]

In the annealing step (S3), first epitaxial layer 12A is annealed. Accordingly, carbon 6 is diffused in first epitaxial layer 12A (see FIG. 11), and is combined with and eliminates Z_{1/2} center (see FIG. 12). For example, the annealing is performed at a temperature of about not less than 1400° C. and not more than 1900° C., preferably not less than 1500° C. and not more than 1800° C., more preferably not less than 1600° C. and not more than 1800° C., and particularly preferably not less than 1700° C. and not more than 1800° C. The annealing is performed for, for example, about 1 hour to 5 hours, preferably, about 10 minutes to 3 hours.

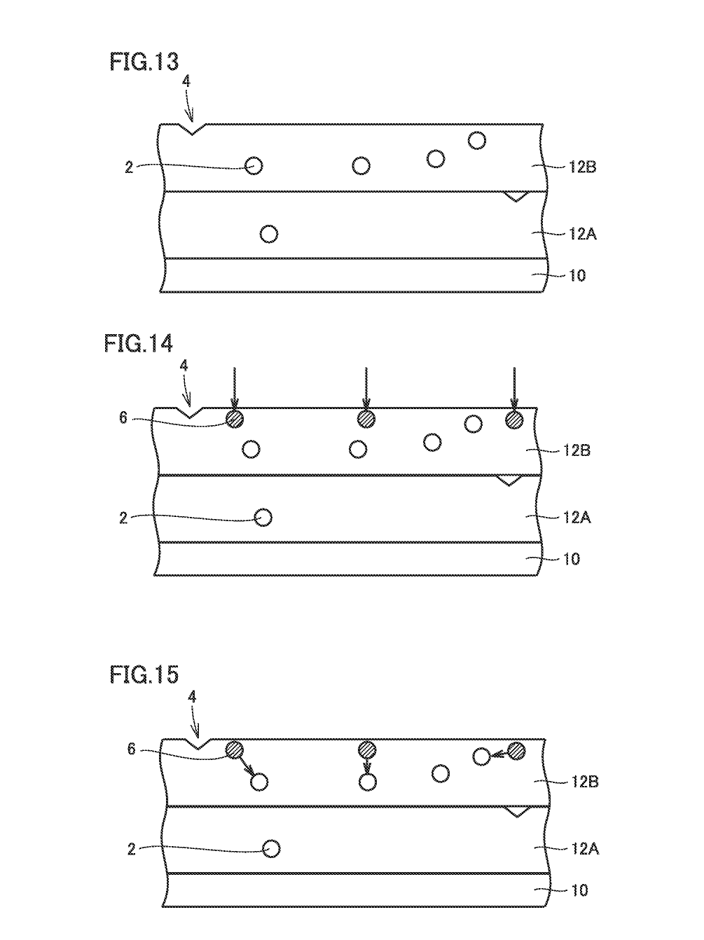

Then, the series of steps (S22) including the epitaxial growth step (S1), the carbon introducing step (S2), and the annealing step (S3) are repeated in the same manner (see FIG. 13 to FIG. 15), thereby forming a second epitaxial layer 12B having reduced Z_{1/2} center.

In the second production method, the series of steps (S22) including the epitaxial growth step (S1), the carbon introducing step (S2), and the annealing step (S3) are repeated once again. That is, in the second production method, the series of steps (S22) are repeated 3 times in total. Accordingly, second SiC layer 12 is formed which includes first epitaxial layer 12A, second epitaxial layer 12B, and a third epitaxial layer 12C as shown in FIG. 16. The thickness of second SiC layer 12 and the thickness of each epitaxial layer are the same as those in first SiC layer 11 described above.

[3. Third Production Method]

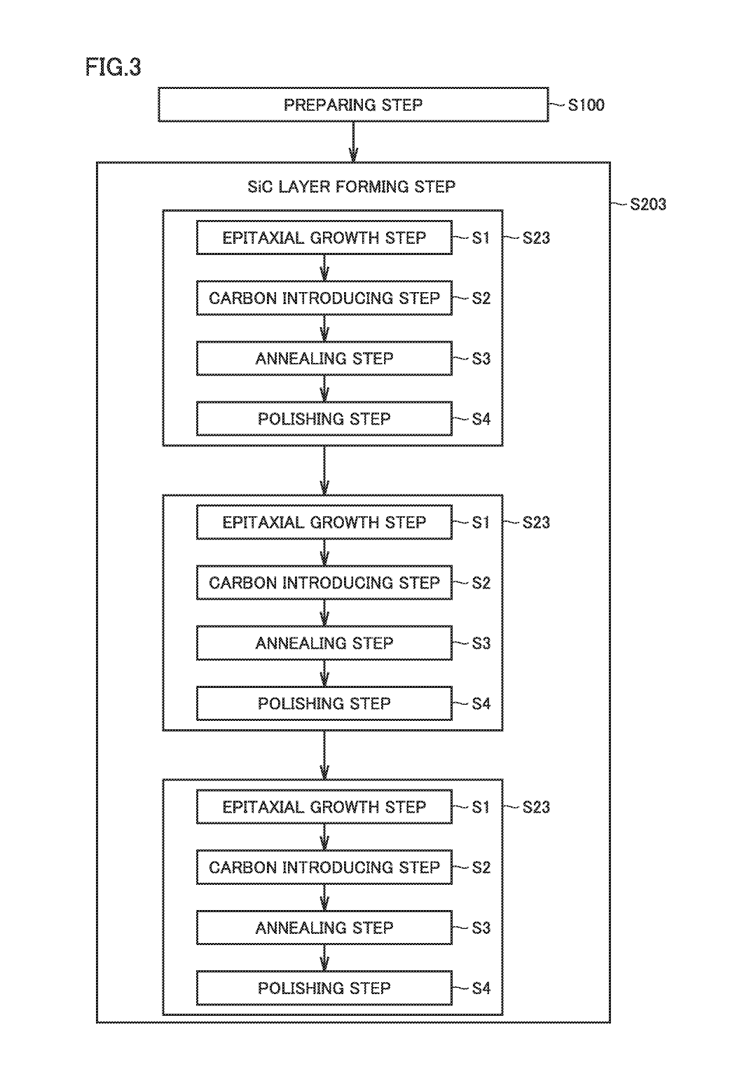

The third production method includes both the configurations of the first and second production methods mentioned above. FIG. 3 is a flowchart schematically showing the third production method. With reference to FIG. 3, the third production method includes the preparing step (S100) and a third SiC layer forming step (S203). In the third production method, in the third SiC layer forming step (S203), a series of steps (S23) including the epitaxial growth step (S1), the carbon introducing step (S2), the annealing step (S3), and the polishing step (S4) are repeated twice or more. However, each of the carbon introducing step (S2) and the annealing step (S3) may be performed once or more. This is because the point defects can be reduced by introducing carbon into at least one epitaxial layer and diffusing it by annealing.

Moreover, as with the second production method, the annealing step (S3) may be performed whenever carbon is introduced into each epitaxial layer, or the annealing step (S3) may be collectively performed once after the uppermost layer is formed. Moreover, in view of the manner of collectively performing the annealing step (S3) once at the end, it is desirable to introduce carbon into at least the uppermost layer.

According to the third production method, third SiC layer 13 (see FIG. 21) is produced which has few included foreign matters and surface defects, has a small step caused by step-bunching, and has reduced point defects. Moreover, according to this method, a damaged layer generated during the introduction of carbon (during the thermal oxidation or the ion implantation) can be also removed by polishing, thereby further improving crystal quality. The preparing step (S100) and the epitaxial growth steps (S1) to the polishing step (S4) in the third production method are the same as those described with regard to the first and second production methods and they are therefore not described repeatedly.

[Third SiC Layer Forming Step (S203)]

With reference to FIG. 3, in the third SiC layer forming step (S203), the series of steps (S23) including the epitaxial growth step (S1), the carbon introducing step (S2), the annealing step (S3), and the polishing step (S4) are repeated twice or more.

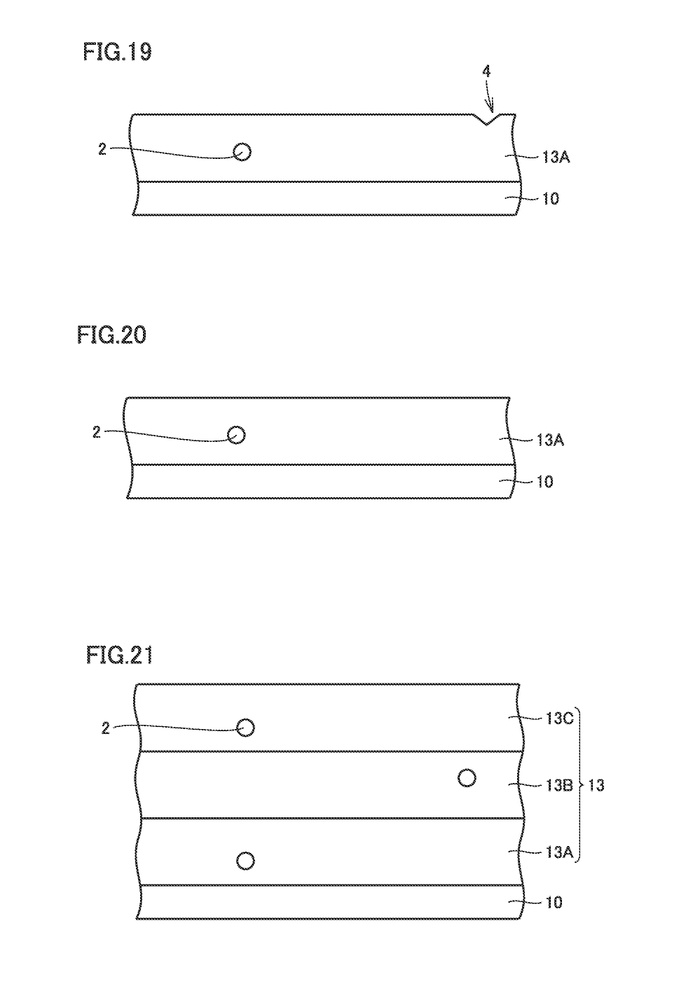

First, with reference to FIG. 17, first epitaxial layer 13A is formed on SiC substrate 10 (S1). Then, with reference to FIG. 17, carbon 6 is introduced into first epitaxial layer 13A (S2). With reference to FIG. 18 and FIG. 19, carbon 6 thus introduced is diffused by annealing and is then combined with and eliminates Z_{1/2} center (S3). Furthermore, in the third production method, with reference to FIG. 20, the annealed surface of first epitaxial layer 13A is polished (S4). Accordingly, in first epitaxial layer 13A, the damaged layer caused by the introduction of carbon and the foreign matters adhered to the surface thereof can be removed, and the step caused by the step-bunching can be reduced.

Then, by repeating the series of steps (S23) twice in the same manner, a third SiC layer 13 is formed which includes first epitaxial layer 13A, second epitaxial layer 13B, and third epitaxial layer 13C as shown in FIG. 21. The thickness of third SiC layer 13 and the thickness of each epitaxial layer are the same as those of first SiC layer 11 and the like.

### Second Embodiment

### Silicon Carbide Epitaxial Substrate

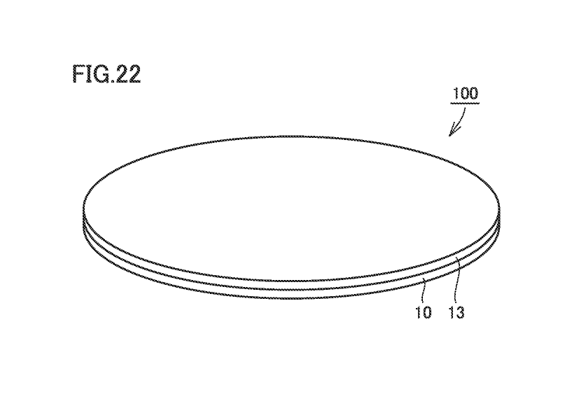

A second embodiment presents a SiC epitaxial substrate. FIG. 22 is a schematic view showing an example of a configuration of a SiC epitaxial substrate (wafer) according to the second embodiment. With reference to FIG. 22, SiC epitaxial substrate 100 includes SiC substrate 10 and third SiC layer 13 epitaxially grown on SiC substrate 10. SiC epitaxial substrate 100 preferably has a diameter of not less than 100 mm (for example, not less than 4 inches), and more preferably has a diameter of not less than 150 mm (for example, not less than 6 inches).

SiC epitaxial substrate 100 is typically obtained by the third production method mentioned above. Therefore, third SiC layer 13 has few defects resulting from inclusion of foreign matters and has high crystal quality. Moreover, because the surface of third SiC layer 13 is free of step-bunching, high reliability can be expected in an oxide film when the oxide film is formed thereon. Therefore, SiC epitaxial substrate 100 is useful for any types of semiconductor devices including unipolar and bipolar semiconductor devices.

Furthermore, although third SiC layer 13 includes Z_{1/2} center 2, an amount of Z_{1/2} center 2 is reduced in a range from the surface layer to the deep layer. Therefore, it is particularly suitable for a bipolar semiconductor device having high breakdown voltage. The thickness of third SiC layer 13 is preferably not less than 100 μm and not more than 400 μm, and is more preferably not less than 200 μm and not more than 300 μm.

Distribution of Z_{1/2} center 2 in the depth direction of third SiC layer 13 can be measured by, for example, a DLTS (Deep Level Transient Spectroscopy) method. FIG. 23 is a graph showing a change in density of Z_{1/2} center 2 in the depth direction of third SiC layer 13 (curve CL1). The horizontal axis of FIG. 23 represents a position in the depth direction of third SiC layer 13, whereas the vertical axis represents a density of Z_{1/2} center 2 in each depth position.

With reference to curve CL1 of FIG. 23, maximum value Pz of the density of Z_{1/2} center 2 in the depth direction of third SiC layer 13 is at a position separated from an interface between SiC substrate 10 and third SiC layer 13. This is because the carbon introducing step (S2) has been performed for first epitaxial layer 13A and second epitaxial layer 13B during the formation of third SiC layer 13. In contrast, if carbon is introduced only in the surface layer of the thick SiC layer, the maximum value of the density of Z_{1/2} center 2 appears at the interface between the SiC substrate and the SiC layer as indicated by curve CL2 and becomes larger than maximum value Pz.

Maximum value Pz is preferably not more than 5×10¹¹ cm⁻³ because the carrier lifetime can be made longer. Maximum value Pz is more preferably not more than 4×10¹¹ cm⁻³ and is particularly preferably not more than 3×10¹¹ cm³. In view of the carrier lifetime, smaller maximum value Pz is more preferable, but maximum value Pz is preferably not less than 1×10¹⁰ cm³ when the switching characteristic of the semiconductor device is also taken into consideration.

Moreover, third SiC layer 13 is formed by the stepwise epitaxial growth and therefore has a configuration resulting therefrom. FIG. 24 is a graph showing a change in concentration of a p type or n type impurity (dopant) in the depth direction of third SiC layer 13. With reference to FIG. 24, there are a plurality of peaks of the concentration of the p type or n type impurity (dopant) in the depth direction of third SiC layer 13, and at least one of them is at a position separated from the interface between SiC substrate 10 and third SiC layer 13 because the concentration of the dopant becomes slightly high in an early stage of epitaxial growth. In contrast, if continuous epitaxial growth is performed, there is usually one peak of the impurity in the depth direction and the position of the peak is in the vicinity of the interface between the SiC substrate and the SiC layer.

Here, examples of the p type impurity include aluminum (Al), boron (B), and the like, whereas examples of the n type impurity include nitrogen (N), phosphorus (P), and the like. The change in concentration of the impurity in the depth direction can be measured by, for example, a SIMS (Secondary Ion Mass Spectrometry) method.

Moreover, a peak interval of the impurity corresponds to the thickness of each epitaxial layer when the epitaxial growth is performed stepwisely. Therefore, as with the thickness of each epitaxial layer described with respect to the epitaxial growth step (S1), the peak interval is preferably not less than 50 μm and not more than 100 μm, more preferably, not less than 60 μm and not more than 90 μm, and particularly preferably not less than 70 μm and not more than 80 μm.

### Third Embodiment

### Silicon Carbide Semiconductor Device

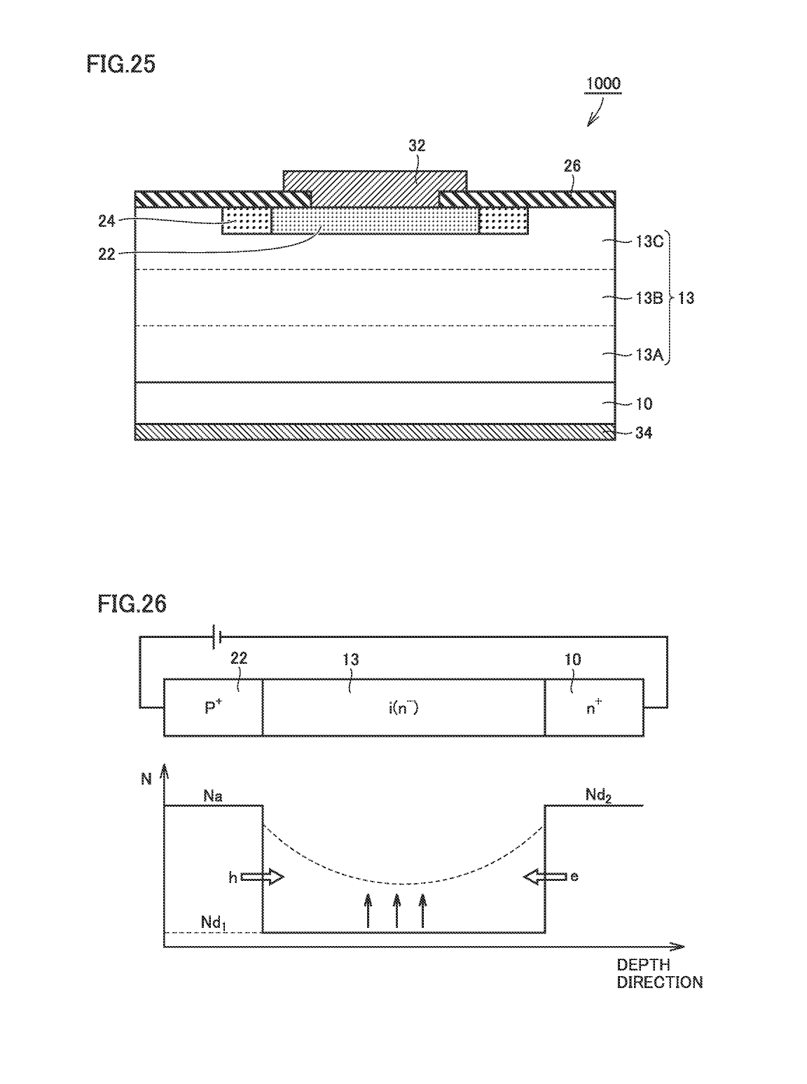

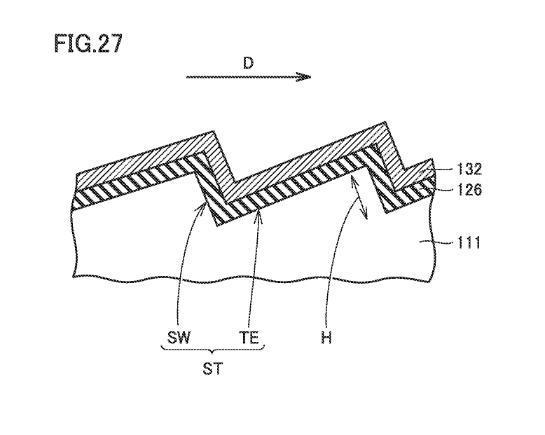

A third embodiment presents a SiC semiconductor device obtained using the SiC epitaxial substrate of the second embodiment. FIG. 25 is a schematic cross sectional view showing an example of a configuration of the SiC semiconductor device according to the third embodiment. A SiC semiconductor device 1000 shown in FIG. 25 is a planar type PiN diode. SiC semiconductor device 1000 includes SiC substrate 10 and third SiC layer 13 epitaxially grown thereon. Third SiC layer 13 includes first epitaxial layer 13A, second epitaxial layer 13B, and third epitaxial layer 13C, which have been grown stepwisely.

Third SiC layer 13 serves as a drift layer. In third SiC layer 13, a p⁺ region 22 and a JTE region 24 are formed by ion implantation, for example. JTE region 24 is a p type region, and serves to relax electric field concentration at an end portion of pn junction. Moreover, an oxide film 26 and an anode electrode 32 are provided on third SiC layer 13, while a cathode electrode 34 is provided at an opposite side of SiC substrate 10 to a side in contact with third SiC layer 13.

FIG. 26 is a schematic view illustrating conductivity modulation in SiC semiconductor device 1000 (PiN diode). In order to increase the breakdown voltage of the device, the thickness of third SiC layer 13 (n⁻ region) needs to be large and doping concentration Nd₁ thereof needs to be low. Nd₁ is about 1×10¹⁴ cm⁻³, for example. On this occasion, p⁺ region 22 has a doping concentration Na of, for example, about 1×10¹⁹ cm⁻³ and SiC substrate 10 (n⁺ region) has a doping concentration Nd₂ of, for example, about 1×10¹⁸cm⁻³.

When this device is supplied with electric current, positive holes (h) are injected from p⁺ region 22 to third SiC layer 13 (n⁻ region) and electrons (e) are injected from SiC substrate 10 (n⁺ region) to third SiC layer 13 (n⁻ region). When the diffusion length of the carriers (positive holes and electrons) injected on this occasion is sufficiently long, the carrier density greatly exceeds the original doping concentration Nd₂ throughout third SiC layer 13, whereby the conductivity of third SiC layer 13 is increased apparently. That is, the resistance in the on state (on resistance) becomes low.

However, here, if Z_{1/2} center exists in third SiC layer 13, a defect level resulting from Z_{1/2} center is formed between an acceptor level and a donor level. In the defective level, the positive holes and the electrons are combined with each other again, thereby reducing the carrier lifetime and the diffusion length. Therefore, when the density of Z_{1/2} center in third SiC layer 13 is high, a sufficient effect of conductivity modulation is not attained to result in high on resistance.

As described above, third SiC layer 13 is obtained from the SiC epitaxial substrate of the second embodiment. Therefore, in third SiC layer 13, the density of Z_{1/2} center is low throughout the entire region in the depth direction, and the density is suppressed to, for example, not more than 5×10¹¹ cm⁻³ at maximum. Therefore, in SiC semiconductor device 1000, sufficient conductivity modulation takes place and low on resistance is attained. Furthermore, third SiC layer 13 can be a thick epitaxial layer of not less than 100 μm and therefore can exhibit a very high breakdown voltage.

In the description above, the present embodiment has been described with regard to the PiN diode but the present embodiment is not limited to this and can be widely applied to bipolar semiconductor devices such as a BJT (Bipolar Junction Transistor), an IGBT (Insulated Gate Bipolar Transistor), a JBS (Junction Barrier Schottky Diode), and a thyristor. Furthermore, the present embodiment can be also widely applied to unipolar semiconductor devices such as a MOSFET, a JFET (Junction Field Effect Transistor), and a SBD (Schottky Barrier Diode).

Although the present invention has been described and illustrated in detail, it is clearly understood that the same is by way of illustration and example only and is not to be taken by way of limitation, the scope of the present invention being interpreted by the terms of the appended claims.

1-13. (canceled)

14. A silicon carbide epitaxial substrate comprising a silicon carbide substrate, and a silicon carbide layer epitaxially grown on said silicon carbide substrate,
said silicon carbide layer including Z_{1/2} center,
a maximum value of a density of 2₁₁₂ center being at a position separated from an interface between said silicon carbide substrate and said silicon carbide layer in a depth direction of said silicon carbide layer.

15. The silicon carbide epitaxial substrate according to claim 14, wherein said maximum value is not more than 5×10¹¹ cm⁻³.

16. The silicon carbide epitaxial substrate according to claim 14, wherein
said silicon carbide layer further includes a p type or n type impurity, and
a peak of a concentration of said impurity is at a position separated from said interface in said depth direction.

17. The silicon carbide epitaxial substrate according to claim 16, wherein a plurality of peaks of the concentration of said impurity exist in said depth direction.

18. The silicon carbide epitaxial substrate according to claim 16, wherein a peak interval of the concentration of said impurity is not less than 50 μm and not more than 100 μm in said depth direction.

19. The silicon carbide epitaxial substrate according to claim 14, wherein said silicon carbide layer has a thickness of not less than 100 μm.

20. A silicon carbide semiconductor device obtained using the silicon carbide epitaxial substrate recited in claim 14.
